(19) United States
(12) Patent Application Publication
(10) Pub. No.: US 2026/0239881 A1
(43) Pub. Date: Aug. 13, 2026

(54) SEMICONDUCTOR DEVICE AND METHOD OF FORMING THE SAME

(71) Applicant: TAIWAN SEMICONDUCTOR MANUFACTURING COMPANY LTD., HSINCHU (TW)

(72) Inventors: YI-HSIEN CHANG, CHANGHUA COUNTY (TW); WEN-CHUAN TAI, HSINCHU CITY (TW); FU-CHUN HUANG, HSINCHU COUNTY (TW); CHUN-REN CHENG, HSINCHU CITY (TW); SHIH-FEN HUANG, HSINCHU COUNTY (TW)

(21) Appl. No.: 19/047,669

(22) Filed: Feb. 7, 2025

(51) Int. Cl. H10N 30/20; B06B 1/02; B06B 1/06; B81B 3/00; B81C 1/00; H01L 23/00; H01L 25/16; H04R 19/02

(52) U.S. Cl. CPC H10N 30/2047; B06B 1/0207; B06B 1/0292; B06B 1/0603; B81B 3/0021; B81C 1/0023; H04R 19/02; H10W 90/00; B81B 2201/0271; B81B 2203/0127; H10W 90/752

(57) ABSTRACT

A semiconductor device is provided. The semiconductor device includes a first microelectromechanical system (MEMS) structure over a first substrate, and a second MEMS structure on a second substrate. The first MEMS structure includes a first flexible membrane and a first cavity between the first substrate and the first flexible membrane. The second substrate is bonded to a conductive layer over the first substrate, and the second MEMS structure is stacked above the first MEMS structure. The second MEMS structure includes a second flexible membrane overlying a second cavity of the second substrate, and the second cavity is positioned above the first cavity. The first MEMS structure and the second MEMS structure are independently coupled to an interconnect structure over the first substrate.

### BACKGROUND

Microelectromechanical systems (MEMS) devices are micro-sized devices that include a number of elements (e.g., stationary or movable elements) for achieving electro-mechanical functionality. MEMS devices are often made using micro-fabrication techniques. In recent years, MEMS devices have found a wide range of applications, and are commonly included in modern-day electronics. For example, MEMS devices are found in cell phones (e.g., accelerometers, gyroscopes, and digital compasses), pressure sensors, micro-fluidic elements (e.g., valves, pumps), optical switches (e.g., mirrors), imaging devices (e.g., micromachined ultrasonic transducers (MUTs)), etc. Among the various applications of MEMS technologies, MUTs have gained widespread attention due to their superior performance compared to conventional ultrasonic sensors.

### BRIEF DESCRIPTION OF THE DRAWINGS

Aspects of the present disclosure are best understood from the following detailed description when read with the accompanying figures. It should be noted that, in accordance with the standard practice in the industry, various features are not drawn to scale. In fact, the dimensions of the various features may be arbitrarily increased or reduced for clarity of discussion.

FIG. 1 is a block schematic diagram of a semiconductor device including microelectromechanical system (MEMS) structures, in accordance with some embodiments of the present disclosure.

FIG. 2 illustrates a diagrammatic simplification of a semiconductor device including MEMS structures of some embodiments, which is similar to that described in FIG. 1.

FIG. 3 illustrates a cross-sectional view of a semiconductor device, in accordance with some embodiments of the present disclosure.

FIG. 4 is a flowchart illustrating a method of forming a semiconductor device, in accordance with some embodiments of the present disclosure.

FIGS. 5A-5I are fragmentary cross-sectional views of a semiconductor device at different stages of fabrication in accordance with some embodiments of the method shown in FIG. 4.

FIG. 6 illustrates a cross-sectional view of a semiconductor device, in accordance with some embodiments of the present disclosure.

FIG. 7A illustrates a diagrammatic simplification of an assembly structure including a semiconductor device in accordance with some embodiments of the present disclosure.

FIG. 7B illustrates a diagrammatic simplification of another assembly structure including a semiconductor device in accordance with some embodiments of the present disclosure.

FIGS. 8A, 8B and 8C are schematic top views illustrating a region of a second MEMS structure above the first MEMS structures, in accordance with some embodiments of the present disclosure.

### DETAILED DESCRIPTION

The following disclosure provides many different embodiments, or examples, for implementing different features of the provided subject matter. Specific examples of elements and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

As used herein, the terms such as “first,” “second” and “third” describe various elements, components, regions, layers and/or sections, but these elements, components, regions, layers and/or sections should not be limited by these terms. These terms may be only used to distinguish one element, component, region, layer or section from another. The terms such as “first,” “second” and “third” when used herein do not imply a sequence or order unless clearly indicated by the context.

Notwithstanding that the numerical ranges and parameters setting forth the broad scope of the disclosure are approximations, the numerical values set forth in the specific examples are reported as precisely as possible. Any numerical value, however, inherently contains certain errors necessarily resulting from the standard deviation found in the respective testing measurements. Also, as used herein, the terms “substantially,” “approximately” or “about” generally mean within a value or range that can be contemplated by people having ordinary skill in the art. Alternatively, the terms “substantially,” “approximately” or “about” mean within an acceptable standard error of the mean when considered by one of ordinary skill in the art. People having ordinary skill in the art can understand that the acceptable standard error may vary according to different technologies. Other than in the operating/working examples, or unless otherwise expressly specified, all of the numerical ranges, amounts, values and percentages such as those for quantities of materials, durations of times, temperatures, operating conditions, ratios of amounts, and the like thereof disclosed herein should be understood as modified in all instances by the terms “substantially,” “approximately” or “about.” Accordingly, unless indicated to the contrary, the numerical parameters set forth in the present disclosure and attached claims are approximations that can vary as desired. At the very least, each numerical parameter should at least be construed in light of the number of reported significant digits and by applying ordinary rounding techniques. Ranges can be expressed herein as from one endpoint to another endpoint or between two endpoints. All ranges disclosed herein are inclusive of the endpoints, unless specified otherwise.

In some embodiments, a semiconductor device includes integrated microelectromechanical system (MEMS) structures. The MEMS structures includes a cavity and a flexible membrane. The configuration (e.g., structural configuration) of the MEMS structures is dependent on the types of MEMS structures. In some embodiments, the MEMS structures of different types are integrated to form a semiconductor device. At least one of the MEMS structures is configured to operate as an ultrasound pump, and at least one of the MEMS structures is configured to operate as a frequency modulator. Thus, the semiconductor device of the embodiments provides a single transducer solution, by integration of a pump-type MEMS structure and a modulator-type MEMS structure, to replace multi-speaker assembly.

Typically, the semiconductor device only includes MEMS devices of the same type. For example, if the semiconductor device includes the CMUTs, the semiconductor device will only includes CMUTs. On the other hand, if the semiconductor device includes the PMUTs, the semiconductor device will only include PMUTs. Thus, a single semiconductor device includes different types of MEMS devices has several advantages, such as reduction of manufacturing costs, reduction of packaging sizes, reduction of power consumption, etc.

Various embodiments of the present application are directed toward a semiconductor device and a method for forming the semiconductor device. The semiconductor device includes integrated MEMS structures of different types. The first MEMS structure, such as a capacitive micromachined ultrasonic transducer (CMUT), is configured to operate as an ultrasound pump. The second MEMS structure, such as a piezoelectric micromachined ultrasonic transducer (PMUT), is disposed above the first MEMS structure and configured to operate as a frequency modulator. In some embodiments, the voltages, capacitances and frequencies of the integrated MEMS structures can be directly controlled by ASIC CMOS, thereby improving the reliability and performance of the semiconductor device. In addition, the semiconductor device of some embodiments is fabricated using a semiconductor process, resulting in high yield and low performance variation.

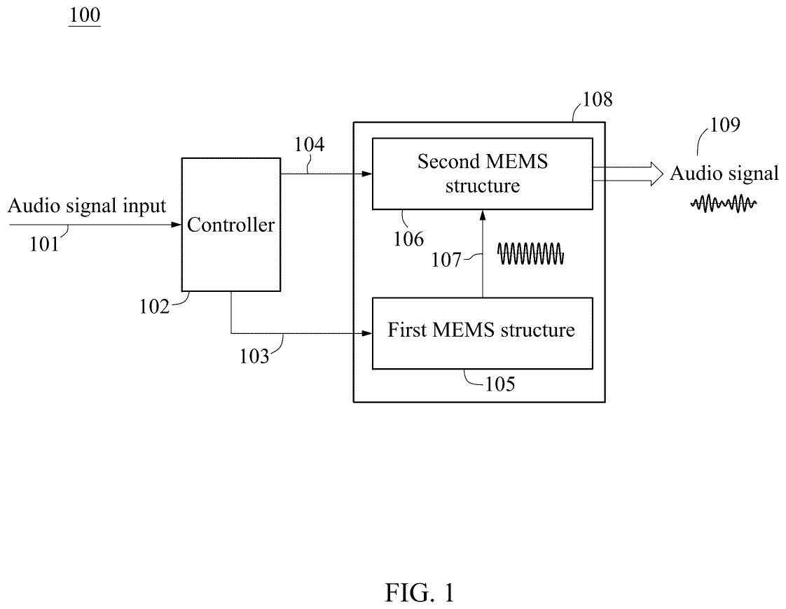

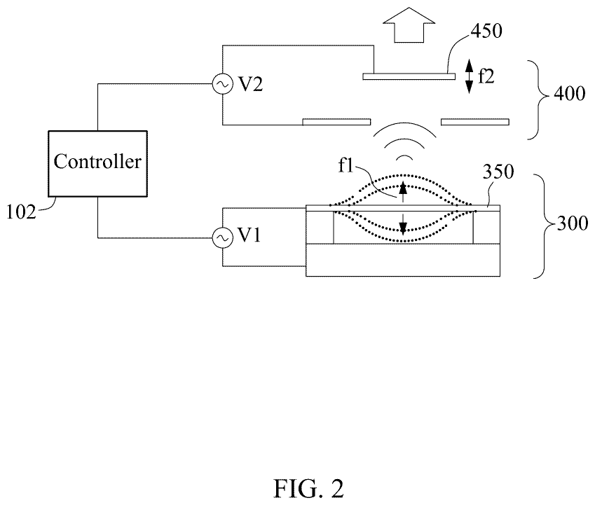

The various aspects of the present disclosure will now be described in more detail with reference to the figures. FIG. 1 is a block schematic diagram of a semiconductor device 100 including microelectromechanical system (MEMS) structures, in accordance with some embodiments of the present disclosure. FIG. 2 illustrates a diagrammatic simplification of a semiconductor device including MEMS structures of some embodiments, which is similar to that described in FIG. 1.

Referring to FIG. 1 and FIG. 2, in some embodiments, the audio signal input 101 is applied to the control block 102. The control block 102 generates stimulus frequency signals 103 and 104 to the semiconductor device block 108. The semiconductor device block 108 includes the first MEMS structure block 105 and the second MEMS structure block 106. The stimulus frequency signal 103 is applied to the first MEMS structure (block 105), and the stimulus frequency signal 104 is applied to the second MEMS structure (block 106). The flexible membrane of the first MEMS structure oscillates or vibrates at the frequency (e.g., the first frequency f1 in FIG. 2) according to the stimulus frequency signal 103. In some embodiments, the flexible membrane of the first MEMS structure (block 105) vibrates at an ultrasound frequency. The first MEMS structure may include one or more first MEMS ultrasonic transducers. The stimulus frequency signal 104 is applied to the second MEMS structure (block 106). The flexible membrane of the second MEMS structure 106 oscillates or vibrates at the frequency (e.g., the second frequency f2 in FIG. 2) according to the stimulus frequency signal 104. The second frequency f2 is less than the first frequency f1. The ultrasonic wave resulting from the flexible membrane vibrations of the first MEMS structure (block 105) is passed to the second MEMS structure (block 106) together with the stimulus frequency signal 104. The second MEMS structure (block 106) modulates the ultrasonic wave resulting from the vibration of the flexible membrane of the first MEMS structure (block 105) to produce a modulated wave at a modulated frequency (e.g., the frequency f in FIG. 2). In some embodiments, the second MEMS structure acts to obstruct and open the air flow from the flexible membrane of the first MEMS structure. The second MEMS structure may include one or more second MEMS ultrasonic transducers. Thus, the first and second MEMS structures have different types, and function as an ultrasound pump and a frequency modulator, respectively. The audio signal 109, having the modulated wave corresponding to the signal input 101 is the result.

In addition, as shown in FIG. 2, in some embodiments, a semiconductor device that includes a first MEMS structure 346 integrated with a second MEMS structure 446. A controller, such as a part of a CMOS circuit, generates actuation voltages required in order to vibrate the membranes of the first MEMS structure 346 and the second MEMS structure 446. For example, a first actuation voltage V1 is generated to vibrate the first flexible membrane 350 of the first MEMS structure 346 at an ultrasound frequency (such as the first frequency f1), and a sound pressure is accumulated in a cavity of the second MEMS structure 446. That is, the cavity of the second MEMS structure 446 is an ultrasound pumping chamber in the integration of the first MEMS structure 346 and the second MEMS structure 446. A second actuation voltage V2 is generated to vibrate the second flexible membrane 450 of the second MEMS structure 446 at the second frequency f2, resulting in a modulated wave at a modulated frequency f. Actual values of these actuation voltages and the frequencies of vibration depend on the specific type of the actuation scheme. Structural details of some embodiments are described below.

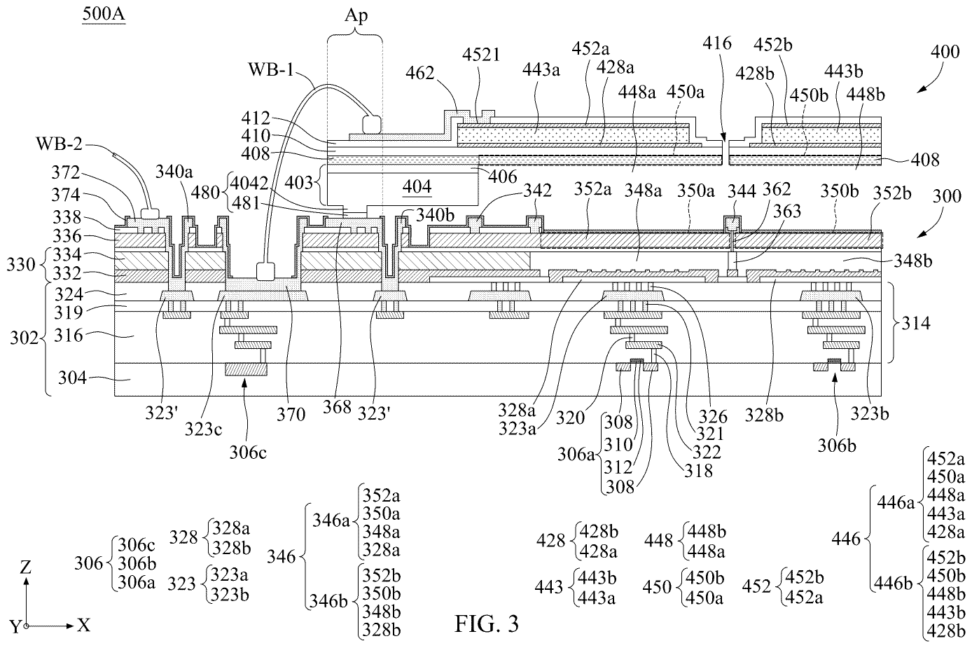

FIG. 3 illustrates a cross-sectional view of a semiconductor device 500A, in accordance with some embodiments of the present disclosure. The semiconductor device 500A includes a first semiconductor structure 300 having a first MEMS structure, and a second semiconductor structure 400 having a second MEMS structure. In some embodiments, the first MEMS structure and the second MEMS structure are micromachined ultrasonic transducers (MUTs) that are able to convert electrical energy to mechanical energy and vice versa. MUTs are often used to transmit and receive acoustic signals in the ultrasonic range (e.g., at frequencies of greater than approximately 20 kHz). In some embodiments, two different types of MUTs, capacitive micromachined ultrasonic transducers (CMUTs) and piezoelectric micromachined ultrasonic transducers (PMUTs), are integrated to form the semiconductor device 500A. A CMUT operates by generating a capacitive force in response to a received acoustic signal and/or by generating an acoustic signal using a capacitive force that is based upon applied electrical signals. A PMUT operates by generating a piezoelectric force in response to a received acoustic signal and/or by generating an acoustic signal using a piezoelectric force that is based upon applied electrical signals.

In some embodiments, the first MEMS structure has a first configuration that corresponds to a capacitive micromachined ultrasonic transducer (CMUT) and can be operated as an ultrasound pump. The second semiconductor structure has a second configuration that corresponds to a piezoelectric micromachined ultrasonic transducer (PMUT) and can be operated as a frequency modulator. In addition, in some embodiments, the second semiconductor structure 400 is bonded to the first semiconductor structure 300 to form the semiconductor device 500A, wherein the second MEMS structure is positioned above the first MEMS structure.

Referring to FIG. 3, in some embodiments, the first semiconductor structure 300 includes an integrated circuit (IC) structure 302 and a MEMS structure over the IC structure 302. The MEMS structure may include several MEMS ultrasonic transducers, such as CMUTs. In some embodiments, the IC structure 302 includes a substrate 304. The substrate 304 may include any type of semiconductor body, such as monocrystalline silicon (CMOS bulk), silicon-germanium (SiGe), silicon on insulator (SOI), etc.

In some embodiments, the IC structure 302 includes several IC devices 306, an interconnect structure 314, a first dielectric structure 316, a second dielectric structure 319, a third dielectric structure 324, and several electrodes 328 over the substrate 304.

In some embodiments, one or more IC devices 306 are disposed on the substrate 304. The IC devices 306 may be or include active electronic devices (e.g., transistors), passive electronic devices (e.g., resistors, capacitors, inductors, fuses, etc.), another electronic devices, or a combination of the foregoing devices. For example, one of the IC devices 306 may be a metal-oxide-semiconductor field-effect transistor (MOSFET) that includes source/drain regions 308 disposed in the substrate 304, a gate dielectric layer 310 disposed over the substrate 304 and between the source/drain regions 308, and a gate electrode 312 disposed over the substrate 304 and overlying the gate dielectric layer 310. For clarity, only some of the IC devices 306 are specifically labeled. In further embodiments, the IC structure 302 is a complementary metal-oxide-semiconductor (CMOS) structure and the IC devices 306 are part of a CMOS circuit.

In some embodiments, the interconnect structure 314 includes one or more first conductive contacts 318, one or more first conductive vias 320, one or more first conductive lines 322, several second conductive vias 321, several second conductive lines 323, and several third conductive vias 326. The first dielectric structure 316, the second dielectric structure 319, and the third dielectric structure 324 are sequentially formed over the substrate 304. The first conductive contacts 318, the first conductive vias 320, and the first conductive lines 322 are embedded in the first dielectric structure 316. The second conductive vias 321 and the second conductive lines 323 (such as lines 323a and 323b) are embedded in the second dielectric structure 319. The third conductive vias 326 and the electrodes 328 (such as the bottom electrodes 328a and 328b) are embedded in the third dielectric structure 324. In some embodiments, the first conductive contacts 318, the first conductive vias 320, and the first conductive lines 322 are referred to as a CMOS interconnect structure. The CMOS interconnect structure interconnects the IC devices 306 together in a predefined pattern.

In addition, the interconnect structure 314 electrically couples the IC devices 306 to the electrodes 328. In this exemplary embodiment, the interconnect structure 314 electrically couples the IC devices 306a and 306b to the bottom electrodes 328a and 328b, respectively. Only some of conductive lines, conductive vias and dielectric layers are depicted and/or specifically labeled for the purpose of simplicity and clarity.

The first conductive contacts 318, the first conductive vias 320, the first conductive lines 322, and/or the third conductive vias 326 may be or include a metal (e.g., copper (Cu), aluminum (Al), tungsten (W), or the like), a metal nitride (e.g., titanium nitride (TiN)), polysilicon (e.g., doped polysilicon), another conductive material, or a combination thereof. The second conductive vias 321 and the second conductive lines 323 may include, for example, a metal (e.g., Al, Cu, aluminum-copper (AlCu), titanium (Ti), silver (Ag), gold (Au), or the like), a metal nitride (e.g., TiN), another conductive material, or a combination thereof. The bottom electrodes 328 (such as the bottom electrodes 328a and 328b) may be or include a metal (e.g., Al, Cu, AlCu, Ti, or the like), a metal nitride (e.g., TiN), another conductive material, or a combination thereof. The first dielectric structure 316, the second dielectric structure 319, and the third dielectric structure 324 each include one or more stacked dielectric layers, such as low-k dielectric material, an oxide (e.g., silicon dioxide), or the like.

A fourth dielectric structure 330, may include the dielectric layers 332 and 334, is disposed over the IC structure 302. The dielectric layer 332 covers the bottom electrodes 328 (such as the bottom electrodes 328a and 328b of the first MEMS structure), and the dielectric layer 334 is formed on the dielectric layer 332. In some embodiments, the dielectric layers 332 and 334 include different dielectric materials. For example, the dielectric layer 332 may include SiN, and the dielectric layer 334 may include SiO₂.

In addition, a MEMS substrate 336 is disposed on the fourth dielectric structure 330. The MEMS substrate 336 may include a semiconductor material (such as polysilicon, amorphous silicon, monocrystalline silicon, SiGe, Ge, or the like), a metal (such as Al, Cu, AlCu), an oxide (such as SiO₂), a nitride (such as SiN), another suitable MEMS substrate, or a combination thereof. The MEMS substrate 336 may be a single semiconductor structure including the semiconductor material. In some embodiments, the MEMS substrate 336 is bonded to the fourth dielectric structure 330 via a bonding process (e.g., fusion bonding), thereby forming a bond interface between the MEMS substrate 336 and the fourth dielectric structure 330.

Another dielectric layer 338 is disposed over the MEMS substrate 336 and the fourth dielectric structure 330. In addition, the fourth conductive vias 340 (such as 340a and 340b) extend vertically through the dielectric layer 338, the MEMS substrate 336, the fourth dielectric structure 330, and the third dielectric structure 324 to contact at least one of the second conductive lines 323′. This ensures that the fourth conductive vias 340 are electrically coupled to the interconnect structure 314. These fourth conductive vias 340 are laterally spaced from one another. In some embodiments, the second conductive contacts 342 are disposed over the dielectric layer 338 and extend through the dielectric layer 338 until reaching the MEMS substrate 336. In addition, the second conductive contacts 342 may be electrically coupled to the interconnect structure 314 via the fourth conductive vias 340b.

The dielectric layer 338 may include an oxide (e.g., SiO₂), a nitride (e.g., SiN), an oxy-nitride (e.g., SiO_{X}N_{Y}), another dielectric material, or a combination thereof. The fourth conductive vias 340 may include a metal (e.g., Al, Cu, AlCu, Ti, Ag, Au, or the like), a metal nitride (e.g., TiN), another conductive material, or a combination thereof. In some embodiments, the fourth conductive vias 340 and the second conductive contacts 342 include the same material.

According to some embodiments, the first semiconductor structure 300 includes the first MEMS structure 346 over the IC structure 302. The first MEMS structure 346 may include one or more MEMS ultrasonic transducers (and may be referred to herein as first MEMS devices). In one exemplary embodiment, the first MEMS structure 346 includes several first MEMS devices 346a and 346b, such as CMUTs. The first MEMS devices each include a flexible membrane above a cavity (may be referred to herein as the first flexible membrane and the first cavity). As shown in FIG. 3, the first flexible membrane 350a of the first MEMS device 346a is laterally spaced from the first flexible membrane 350b of the first MEMS device 346b. The first cavity 348a of the first MEMS device 346a is laterally spaced from the first cavity 348b of the first MEMS device 346b.

In some embodiments, the first MEMS structure 346 further includes the bottom electrode and the top electrode (may be referred to herein as the first bottom electrode and the first top electrode), wherein the cavity is formed between the bottom electrode and the top electrode. As shown in FIG. 3, the first MEMS device 346a includes the first bottom electrode 328a, the first cavity 348a, the first top electrode 352a and the first flexible membrane 350a. The first top electrode 352a may include or be a part of the first flexible membrane 350a. Similarly, the first MEMS device 346b includes the first bottom electrode 328b, the first cavity 348b, the first top electrode 352b and the first flexible membrane 350b. The first top electrode 352b may include or be a part of the first flexible membrane 350b. The first bottom electrode 328a is laterally spaced from the first bottom electrode 328b.

In addition, in some embodiments, the vent holes 362 and the fluid communication channels 363 are further disposed in the fourth dielectric structure 330. For clarity, only one vent hole 362 and one fluid communication channel 363 are depicted in the drawing. The vent hole 362 extends vertically through the MEMS substrate 336. The fluid communication channel 363 extends laterally between two neighboring first cavities 348a and 348b. The vent hole 362 opens up into the fluid communication channel 363. Because the first cavities 348a and 348b are in fluid communication with one another, pressures inside the first cavities 348a and 348b are substantially the same, thereby improving the performance of the first MEMS structure 346.

In addition, in some embodiments, the conductive plugs 344 are disposed over the MEMS substrate 336 and completely cover the vent holes 402. For clarity, only one of the conductive plugs 344 is depicted in the drawings. The conductive plug 344 is configured to hermetically seal the first cavities 348a and 348b and the vent hole 402 at a reference system pressure. In some embodiments, the reference system pressure is less than or equal to 2 standard atmospheres (atm). In further embodiments, the reference system pressure may be less than 0.1 atm (e.g., for a high-vacuum MEMS device). In some embodiments, the conductive plug 344, the fourth conductive vias 340, and the second conductive contacts 342 include the same material. In addition, a passivation layer 374 may be formed as a conformal layer to protect the first semiconductor substrate 300. The passivation layer 374 may be or include an oxide (e.g., SiO₂), a nitride (e.g., SiN), an oxy-nitride (e.g., SiO_{X}N_{Y}), another dielectric material, or a combination thereof.

According to some embodiments, the second semiconductor structure 400 that includes the second MEMS structure 446 is bonded to the first semiconductor structure 300. The second MEMS structure 446 may include one or more MEMS ultrasonic transducers, which may be referred to herein as second MEMS devices. In one exemplary embodiment, the second MEMS structure 446 includes the second MEMS devices 446a and 446b, such as pMUTs. The second MEMS devices each include a flexible membrane overlying a cavity of a substrate, which may be referred to herein as the second flexible membrane, the second cavity, and the second substrate 403.

As shown in FIG. 3, the second flexible membrane 450a of the second MEMS device 446a is laterally spaced from the second flexible membrane 450b of the second MEMS device 446b. The second cavity 448a of the second MEMS device 446a is laterally spaced from the second cavity 448b of the second MEMS device 446b. In addition, after the second semiconductor structure 400 is bonded to the first semiconductor structure 300, the second MEMS structure 446 is stacked above the first MEMS structure 346, and the second cavity 448 is positioned above the first cavity 348. In this exemplary embodiment where the second MEMS devices 446a and 446b respectively correspond to the first MEMS devices 346a and 346b, the second cavity 448a is substantially positioned above the first cavity 348a, and the second cavity 448b is substantially positioned above the first cavity 348b. In addition, the second MEMS devices 446a and 446b are laterally separated by the gap 416.

The flexible membranes of the first MEMS structure 346 and the second MEMS structure 446 are configured to vibrate in response to one or more stimuli (e.g., voltage). In some embodiments, an IC device 306c may be part of an ASIC (application-specific integrated circuit). The IC device 306c is independently coupled to the first MEMS structure 346 and the second MEMS structure 446. For example, the IC device 306c may be configured to operate as a digital signal processor (DSP), a driver circuit, a decoder circuit, or a combination thereof. The actuation voltages may be independently applied to first MEMS structure 346 and the second MEMS structure 446 through the IC device 306c.

In some embodiments, the IC device 306c is a part of a CMOS circuit and configured to operate as a controller. Thus, the IC device 306c may be referred to herein as the controller 306c. In some embodiments, the controller 306c is independently coupled to the first MEMS structure 346 and the second MEMS structure 446. For example, the controller 306c can generate and apply a stimulus, such as a pulse signal, a frequency sweep, an alternating AC voltage, an AC current, etc. to the second MEMS structure 446 (e.g., PMUT) via a top electrode and a bottom electrode at opposite surfaces of an actuation layer (e.g., a piezoelectric layer).

In some embodiments, the second MEMS structure 446 further includes a bottom electrode and a top electrode (may be referred to herein as the second bottom electrode 428 and second top electrode 452). The second MEMS structure 446 further includes an actuator layer 443 between the second bottom electrode 428 and the second top electrode 452. In some embodiments, the actuator layer 443 includes one or more piezoelectric materials, and may be referred to as a piezoelectric actuator layer. In addition, the second flexible membrane 450 is positioned between the second bottom electrode 428 and the second cavity 448 of the second substrate 403.

Specifically, as shown in FIG. 3, the actuator layer 443a is formed between the second bottom electrode 428a and the second top electrode 452a of the second MEMS device 446a, and the second flexible membrane 450a is positioned between the second bottom electrode 428a and the second cavity 448a. The actuator layer 443b is formed between the second bottom electrode 428b and the second top electrode 452b of the second MEMS device 446b, and the second flexible membrane 450b is positioned between the second bottom electrode 428b and the second cavity 448b.

In addition, in some embodiments, the second substrate 403 includes a carrier portion 404 (such as a wafer portion) and an oxide (e.g., BOX) layer 406 between the carrier portion 404 and a structural layer 408 (e.g., a silicon passive membrane layer). In some embodiments, the second flexible membranes 450a and 450b are parts of the structural layer 408. The thickness of the structural layer 408 allows for adjustment of the tuning frequency of the actuator layers 443a and 443b and hence the operation of the PMUT, through the piezoelectric design principles.

In addition, the second semiconductor structure 400 further includes a bonding structure 480 that bonds the second semiconductor structure 400 to the first semiconductor structure 300. The bonding structure 480 extends in a periphery region Ap of the second substrate 403, and has an elongate shape in top view (e.g., extended in the Y direction). In some embodiments, the bonding structure 480 includes a protrusion 4042, and a bond pad 481 formed on the protrusion 4042. The protrusion 4042 protrudes from the bottom surface 404b of the carrier portion 404, and the second substrate 403 is bonded to the conductive layer through the bond pad 481. The protrusion 4042 may be integrally formed with the carrier portion 404.

In some embodiments, the second substrate 403 with the second MEMS structure 446 formed thereon is bonded to a conductive layer 368 over the interconnect structure 314 of the first semiconductor structure 300 via the bonding structure 480. The conductive layer 368 may be electrically coupled to the interconnect structure 314. For example, the conductive layer 368 may be an extending portion of the fourth conductive vias 340 that is coupled to the interconnect structure 314. In some embodiments, the conductive layer 368 includes Al, Cu, aluminum-copper (AlCu), Sn, another suitable material, or a combination thereof.

According to the embodiments, the second MEMS structure 446 is electrically connected to the interconnect structure 314 of the first semiconductor structure 300 for power and signal transmission. In some embodiments, the IC device 306c (e.g., a part of the CMOS circuit) is coupled to the interconnect structure 314 in the first substrate 304, and the operation of the second MEMS structure 446 (e.g., vibrated as a frequency modulator) is controlled by the IC device 306c.

In some embodiments, the second MEMS structure 446 is electrically connected to the interconnect structure 314 by wire bonding. In addition, conductive contacts are formed on the top electrode 452 and the bottom electrode 428. Only one conductive contact 462a formed on the top electrode 452a is depicted in FIG. 3 because the other conductive contact(s) are not shown in the cross-section of FIG. 3. These conductive contacts are electrically connected to the first substrate 304 (e.g., a CMOS substrate) of the first semiconductor structure 300 by wire bonding, such as the interconnect wire WB-1 connecting the conductive contact 462 and a conductive layer 370 of the interconnect structure 314. Accordingly, the power and signal can be transmitted from the circuit in the first substrate 304 to the second MEMS structure 446 through the interconnect wire WB-1.

In addition, the semiconductor device 500A may be electrically connected to an external electrical component (e.g., a printed circuit board or another electrical component) by wire bonding. For example, a conductive contact 372 (as an I/O pad) of the interconnect structure 314 is electrically connected to an external electrical component (not shown) through the interconnect wire WB-1. However, the disclosure is not limited thereto. Other electrical connection methods may be implemented herein.

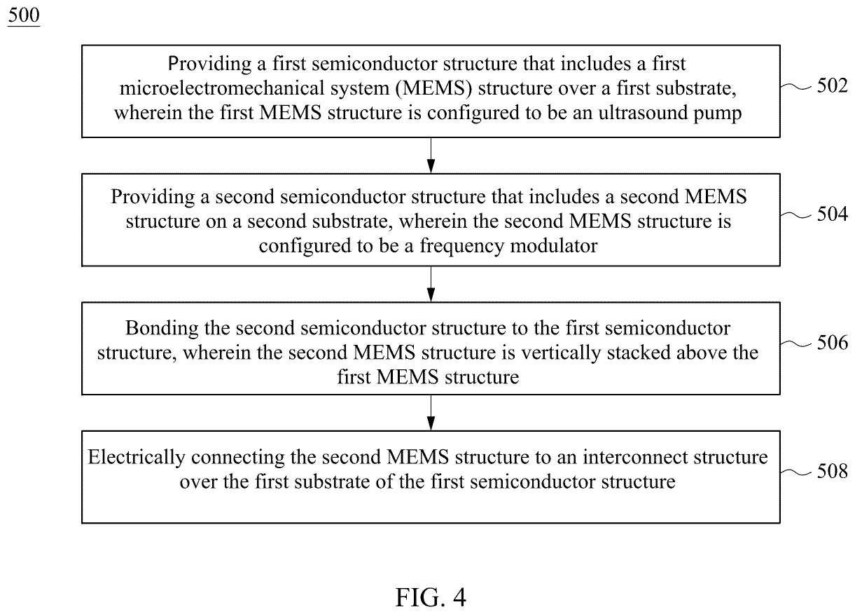

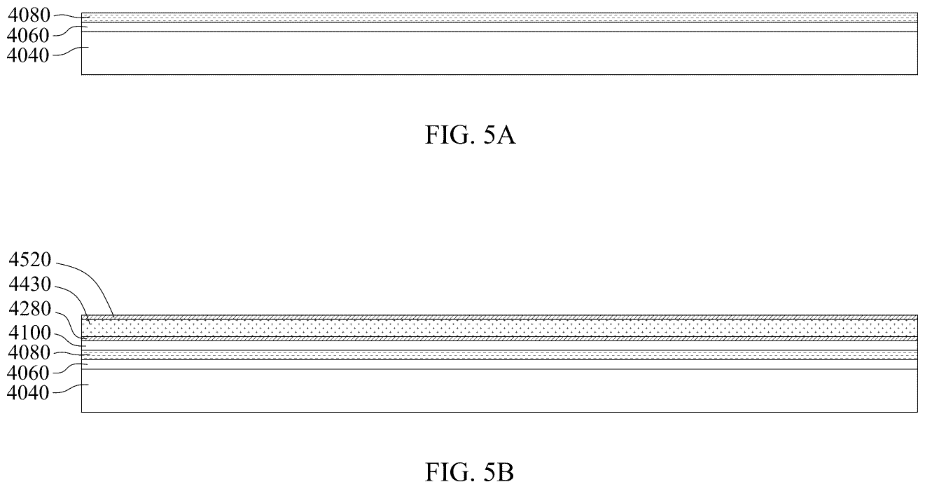

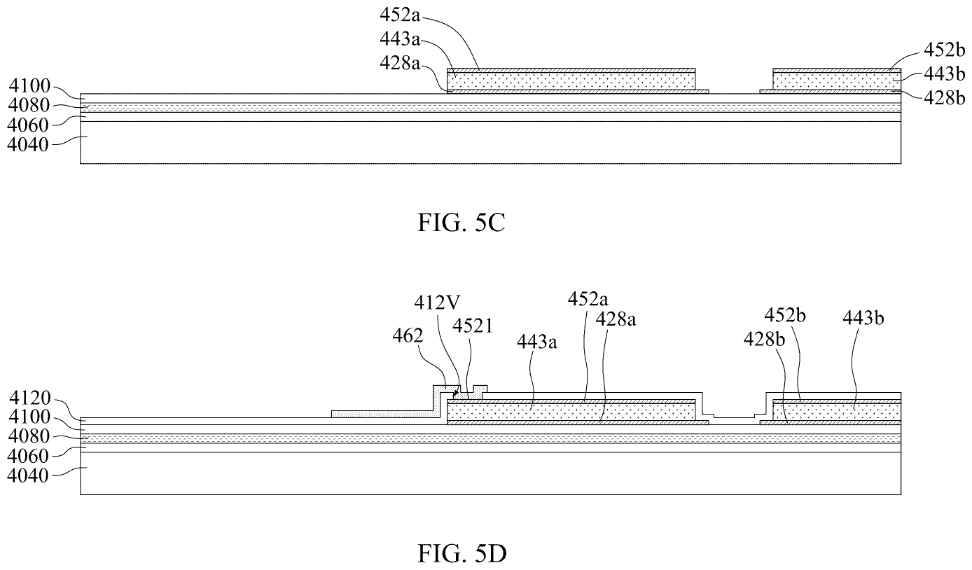

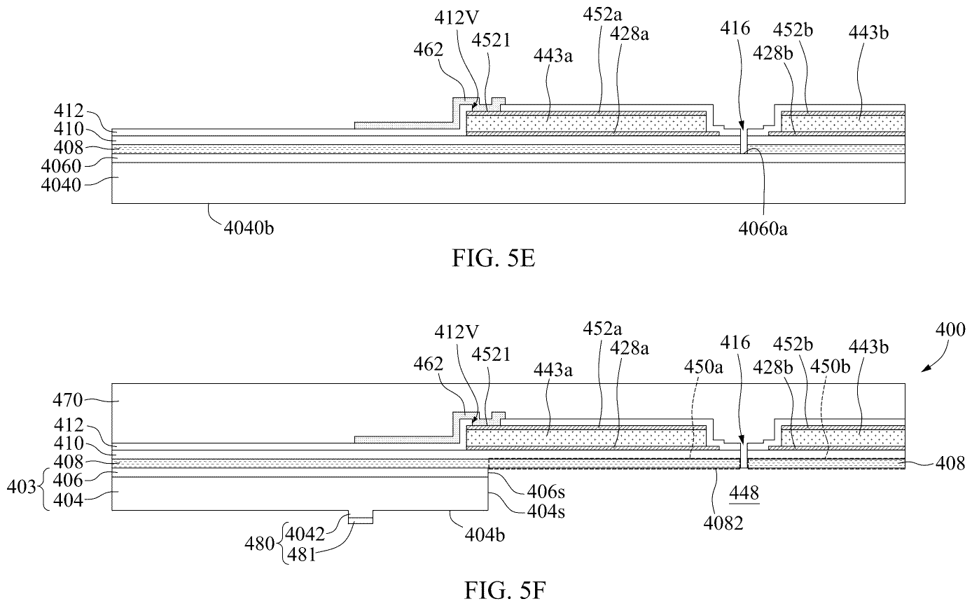

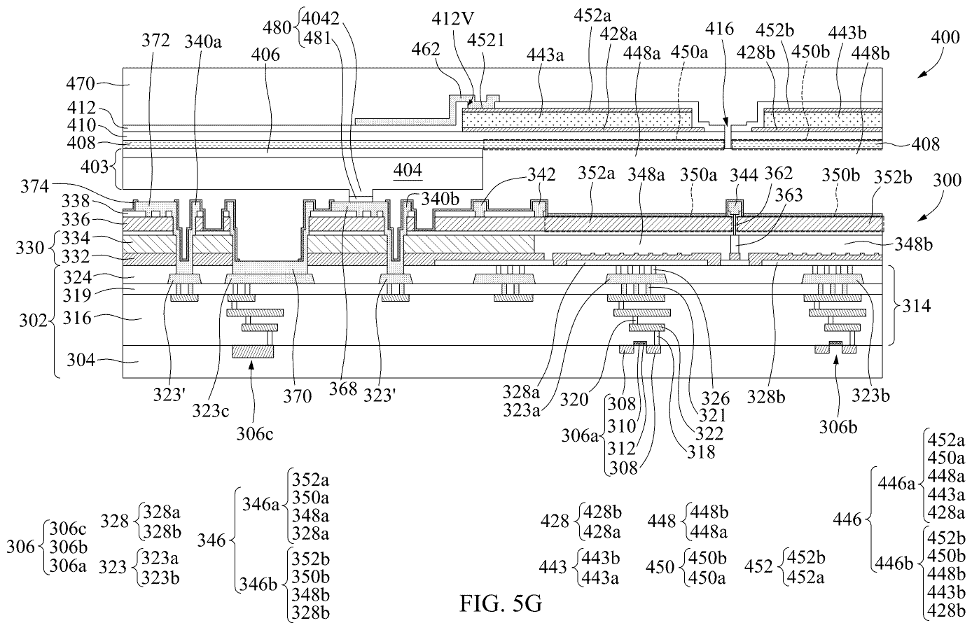

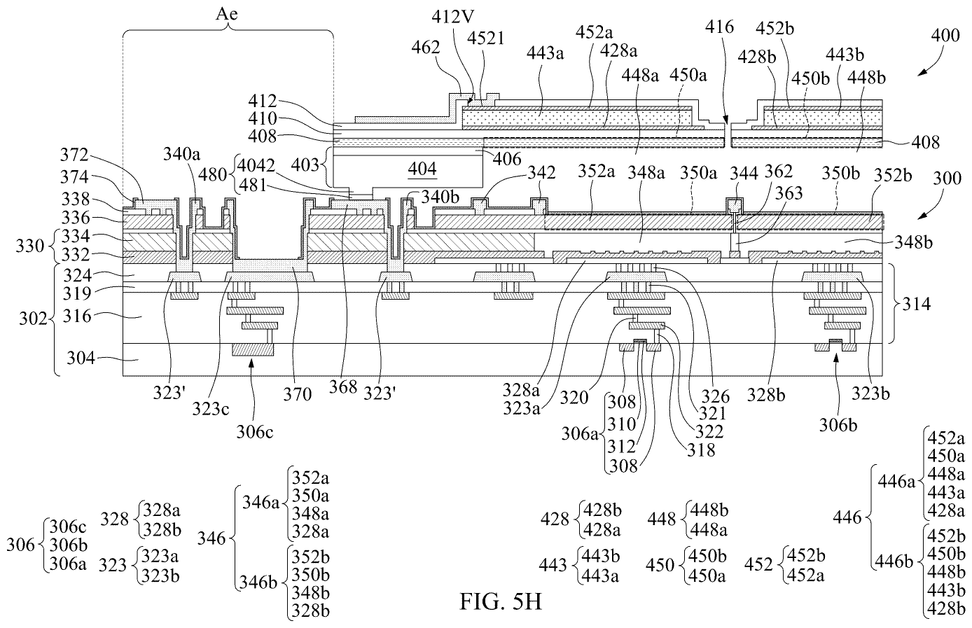

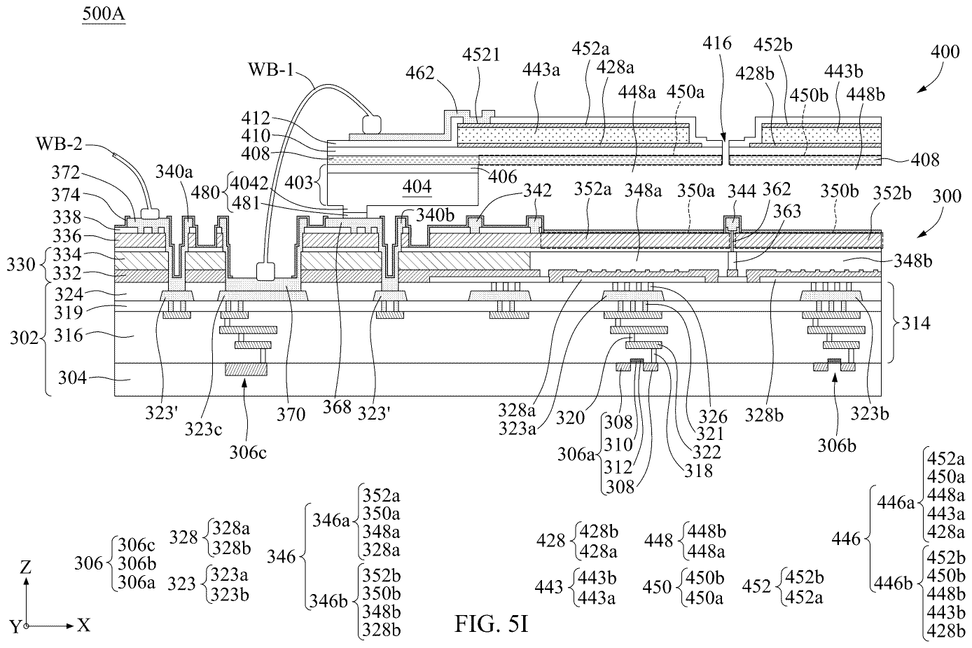

FIG. 4 is a flowchart illustrating a method 500 of forming a semiconductor device 500A, in accordance with some embodiments of the present disclosure. FIGS. 5A-5I are fragmentary cross-sectional views of a semiconductor device 500A at different stages of fabrication in accordance with some embodiments of the method 500 shown in FIG. 4.

The features/components in FIG. 5A-FIG. 5I that are similar or identical to the features/components in FIG. 3 are designated with similar or the same reference numbers, and the details of those similar or the identical features/components are not repeated herein.

Referring to FIG. 4, method 500 includes a block 502 where a first semiconductor structure 300 that includes a first MEMS structure 346 over the first substrate 304 is provided. The first MEMS structure 346 is configured to be an ultrasound pump. Details of the arrangement and materials of the related components of the first semiconductor structure 300 are essentially the same as those discussed in reference to FIG. 3 and are not described again.

Referring to FIGS. 4 and 5A-5F, method 100 includes a block 504 in which a second semiconductor structure 400 is provided. The second semiconductor structure 400 includes a second MEMS structure 446 on a second substrate 403, and the second MEMS structure 446 is configured to be a frequency modulator.

Referring to FIG. 5A, in some embodiments, a substrate that includes several layers is provided. The substrate may be a silicon substrate. In some embodiments, the substrate includes a silicon-on-insulator (SOI) wafer, a piezoelectric-on-insulator (POI) wafer, and bonded wafers as starting materials for fabricating the semiconductor device. In some embodiments, a silicon wafer 4040 is provided as a carrier wafer. The silicon wafer 4040 may have a substantially uniform thickness between approximately 200 μm and approximately 1000 μm. In some embodiments, a buried oxide (BOX) layer 4060 is then deposited on the silicon wafer 4040. The BOX layer 4060 may include SiO₂. The BOX layer 4060 may have a thickness between approximately 1000 Å (or 1 kÅ) and approximately 5 μm. In some embodiments, a device layer 4080 is then formed on the BOX layer 4060. The device layer 4080 may be an SOI device layer, a POI device layer, or another suitable device layer. In some embodiments, the device layer 4080 includes silicon, polysilicon, or another suitable material. In some embodiments, the device layer 4080 has a thickness between approximately 1 kÅ and approximately 50 μm. The device layer 4080 will be patterned to form a passive membrane layer (e.g., the structural layer 408 in FIG. 5H and FIG. 5I) in the subsequent fabrication. The thickness of the device layer 4080 is related to the adjustment of the tuning frequency of the actuator layers of the second MEMS devices (e.g., PMUT) and hence the operation of the second MEMS devices, through the piezoelectric design principles.

Referring to FIG. 5B, in some embodiments, an insulation layer 4100 is formed on the device layer 4080. The insulation layer 4100 may include silicon oxide such as SiO₂, metal oxide such as TiO₂, or another suitable insulation material, and may be formed by thermal oxidation, a chemical vapor deposition (CVD) process, an atomic layer deposition (ALD) process, a physical vapor deposition (PVD) process, or another suitable method. The insulation layer 4100 may have a thickness between approximately 1 kÅ and approximately 10 μm.

In some embodiments, a bottom electrode material layer 4280 is formed on the insulation layer 4100, a piezoelectric actuation material layer 4430 is formed on the bottom electrode material layer 4280, and a top electrode material layer 4520 is formed on the piezoelectric actuation material layer 4430.

The bottom electrode material layer 4280 and/or the top electrode material layer 4520 may be made of electrically conductive materials, typically metals, but not limited to them. Examples of such metals include molybdenum, aluminum, nickel, platinum, copper, cobalt, tungsten, titanium, titanium nitride, tantalum, tantalum nitride, ruthenium, another suitable metal, or a combination thereof. The bottom electrode material layer 4280 and the top electrode material layer 4520 may be formed by CVD, PVD, or another suitable process. The bottom electrode material layer 4280 may have a thickness between approximately 500 angstroms and approximately 1 μm. The top electrode material layer 4520 may have a thickness between approximately 500 angstroms and approximately 10 μm.

The piezoelectric actuation material layer 4430 may include aluminum nitride (AlN), lead zirconate titanate (PZT), zinc oxide (ZnO), polyvinylidene difluoride (PVDF), lithium niobate (LiNbO₃), another suitable piezoelectric material, or a combination thereof. The piezoelectric actuation material layer 4430 may be formed by sol-gel, PVD, or another suitable method. The piezoelectric actuation material layer 4430 may have a thickness between approximately 2000 Å (2 kÅ) and approximately 5 μm.

In some embodiments, the bottom electrode material layer 4280 includes platinum (Pt), and can be formed by PVD. In some embodiments, the top electrode material layer 4520 includes platinum (Pt)/ruthenium (Ru), and can be formed by PVD. In some embodiments, the piezoelectric actuation material layer 4430 includes PZT, and can be formed by sol-gel or PVD.

Next, referring to FIG. 5C, in some embodiments, the top electrode material layer 4520, the piezoelectric actuation material layer 4430 and the bottom electrode material layer 4280 are patterned to form several actuation stacks 40 on the insulation layer 4100. Each of the actuation stacks 40 includes a bottom electrode on the insulation layer 4100, an actuator layer on the bottom electrode, and a top electrode on the actuator layer. In some embodiments, the top electrode material layer 4520, the piezoelectric actuation material layer 4430 and the bottom electrode material layer 4280 can be patterned by using suitable etchants, including a dry etchant (e.g., an ion beam etchant, a reactive-ion etching (RIE), or the similar methods) or a wet etchant (e.g., aqua regia).

As shown in FIG. 5C (and FIG. 3), the actuation stack 40A includes the second bottom electrode 428a, the actuator layer 443a, and the top electrode 452a. The actuation stack 40B includes the second bottom electrode 428b, the actuator layer 443b, and the top electrode 452b. The regions of the actuation stacks 40 on levers (or referred to as beams) can be defined.

Next, referring to FIG. 5D, in some embodiments, further processes for forming components required for PMUTs are performed. For example, a dielectric layer 4120 (e.g., it may be referred to as an intermetal dielectric layer (IMD)) is formed on the insulation layer 4100 to cover the actuation stacks 40. The dielectric layer 4120 is a conformal layer. The dielectric layer 4120 may include Al₂O₃, SiO2, Si₃N₄, or another suitable dielectric material, and may be formed by CVD or another suitable method. The dielectric layer 4120 may have a thickness between approximately 1 kÅ and approximately 5 kÅ.

Then, in some embodiments, the dielectric layer 4120 is patterned to form several vias to expose portions of the top electrodes 452 and the bottom electrodes 428 of the actuation stacks 40. The via 412V that exposes a portion of the top surface 4521 of the top electrode 452a is shown, while the other vias that are not depicted in FIG. 5D are formed in other cross-sections. The dielectric layer 4120 may be patterned by dry etching using an oxide etcher, or by wet etching using a BOE (buffered oxide etchant) solution.

Next, an I/O (input/output) metallization process is performed. In some embodiments, a conductive material layer (not shown) is deposited on the dielectric layer 4120 and fills the vias (e.g., the via 412V and other vias not shown in FIG. 5D). The conductive material layer may include Au, AlCu, Cu, or another suitable conductive material, and may be deposited by PVD or another suitable method. The conductive material layer may have a thickness between approximately 3 kÅ and approximately 8 kÅ for bumping or wire bond in the subsequent process.

Then, the conductive material layer is patterned to form the conductive contacts (e.g., conductive contact 462 and other conductive contacts not shown in FIG. 5D). The conductive material layer may be patterned by ion beam etch, dry metal etch, wet metal etch, or another suitable method. The conductive contact 462 may be referred to as I/O pads, and the process for patterning the conductive material may be referred to as an I/O pad open process. Additionally, a passivation layer (not shown) may be deposited on the conductive material layer before the I/O pad open process to protect the underlying layers, if needed. In some embodiments, there is no need to form a passivation layer. For example, when the conductive contacts 462 (i.e., I/O pads) are Au contacts (i.e., Au pads), no passivation is needed.

Referring to FIG. 5E, in some embodiments, the levers (also referred to as beams) are further defined according to an implemented actuator and modulator design. In some embodiments, the dielectric layer 4120, the insulation layer 4100 and the device layer 4080 are etched sequentially by a lithography patterning process and etching processes (such as anisotropic etching processes) to form the gaps and define the levers. As shown in FIG. 5E, the gap 416 penetrates the dielectric layer 4120, the insulation layer 4100 and the device layer 4080 until reaching the BOX layer 4060. Therefore, the BOX layer 4060 acts as an etch stop layer, and the gap 416 exposes a small portion of the top surface 4060a of the BOX layer 4060.

In some embodiments where the dielectric layer 4120 and the insulation layer 4100 include oxide, oxide etching is performed to remove portions of the dielectric layer 4120 and the insulation layer 4100, thereby forming the dielectric layer 412 and the insulation layer 410. In some embodiments where the device layer 4080 includes silicon, silicon etching is performed to remove a portion of the device layer 4080 without substantially etching the BOX layer 4060. Because the remaining portions of the device layer 4080 will be fabricated as the structures for the adjustment of the tuning frequency of the actuator layers of the second MEMS devices (e.g., PMUT), these remaining portions may be referred to herein as a structural layer 408.

Referring to FIG. 5F, in some embodiments, a sacrificial layer 470 is formed on the dielectric layer 412 to cover the conductive contacts (e.g., 462) and the dielectric layer 412. In some embodiments, the sacrificial layer 470 includes polyimide (PI), epoxy, or any suitable material for protecting the layers and components (e.g., the actuation stacks 40, the dielectric layer 412, and the conductive contact 462) on the front side of the structure in FIG. 5E. In some embodiments, the sacrificial layer 470 fills the gap 416.

In some embodiments, a bonding structure 480 is formed after forming the sacrificial layer 470. For example, backside grinding is performed on the bottom surface 4040b (FIG. 5E) of the silicon wafer 4040, followed by forming a bond pad material layer (not shown) on the bottom surface of the remaining portion of the silicon wafer 4040. The bond pad material layer may be formed on the bottom surface of the remaining portion of the silicon wafer 4040 by eutectic bonding. In some embodiments, the bond pad material layer includes gold (Au), germanium (Ge), silicon (Si), or another suitable material. The bonding process is performed at a temperature without damaging the components of the MEMS structures.

Next, in some embodiments, a patterning process is performed on the bond pad material layer to form a bond pad 481. Then, a stand-off patterning process is performed on the silicon wafer 4040 to form the protrusion 4042. In the stand-off patterning process, the portions of the silicon wafer 4040 that are not covered by the bond pad 481 are removed, resulting in the formation of the protrusion 4042.

Next, in some embodiments, a backside cavity patterning process is performed to remove portions of the silicon wafer 4040 and the BOX layer 406, resulting in a cavity, which is later fabricated into the second cavity 448 of the second MEMS structure, underlying the structural layer 408. In some embodiments, the backside cavity patterning process is performed by silicon etch and oxide etch. In addition, the sacrificial layer 470 acts as a carrier to provide mechanical support in the backside cavity patterning process.

As shown in FIG. 5F, in some embodiments, after the backside cavity is formed, the remaining portion of the silicon wafer 4040 is referred to as a carrier portion 404. The carrier portion 404 and the BOX layer 406 are collectively referred to as the second substrate 403. The protrusion 4042 protrudes from the bottom surface 404b of the carrier portion 404. In addition, the sidewall 406s of the BOX layer 406 is substantially flush with the sidewalls 404s of the carrier portion 404.

According to some embodiments of the present disclosure, a second semiconductor structure 400 that includes a second MEMS structure 446 on the second substrate 403 is provided. After the integration of the second MEMS structure 446 (e.g., configured to operate as a PMUT) and the first MEMS structure 346 (e.g., configured to operate as a CMUT), the second MEMS structure acts as a frequency modulator.

Referring to FIGS. 4 and 5G, method 100 includes a block 506 where the second semiconductor structure 400 is bonded to the first semiconductor structure 300, and the second MEMS structure 446 is vertically stacked above the first MEMS structure 346. WoW (wafer-on-wafer) design or CoW (chip-on-wafer) design may be implemented for the integration of the MEMS structure. After integration, the second cavity 448 of the second semiconductor structure 400 is positioned above the first cavity 348 of the first semiconductor structure 300.

In some embodiments, the second semiconductor structure 400 is stacked on the first semiconductor structure 300 by WoW for integration. The second semiconductor structure 400 may be bonded to the first semiconductor structure 300 by eutectic bond, epoxy bond, thermal compressive bond, or another suitable bonding technology. In one exemplary embodiment, the bonding structure 480 of the second substrate is bonded to the conductive layer 368 over the interconnect structure 314 of the first semiconductor structure 300 by thermal compression bonding. Details of the related positions and connections of the components of the first semiconductor structure 300 and the second semiconductor structure 400 are essentially the same as what has been discussed above, and are not repeatedly described.

Next, referring to FIG. 5H, in some embodiments, the removal of the sacrificial layer 470 and portions of the second semiconductor structure 400 are performed to expose parts of the first semiconductor structure 300 for subsequent electrical connection.

In some embodiments, the sacrificial layer 470 is removed from the second semiconductor structure 400 to expose the second MEMS structure 446. Then, the portions of the stacked films of the second semiconductor structure 400 that are positioned in the region (e.g., the region Ae) outside the bonding structure 480 are removed by etching, to complete the partial dicing. Accordingly, the conductive positions (such as the conductive layer 370 and the conductive contact 372) can be exposed for subsequent electrical connection.

As shown in FIG. 5H, the portions of the second substrate 403, the structural layer 408, the insulation layer 410 and the dielectric layer 412 are removed by partial dicing, so as to expose the conductive contact 372 of the interconnect structure 314.

In some embodiments, a portion of the sacrificial layer 470 that is positioned in the region (e.g., the region Ae) outside the bonding structure 480 is removed, while the other portion of the sacrificial layer 470 still remains to protect the underlying components and layers. Then, the portions of the stacked films (e.g., 403, 408, 410 and 412) of the second semiconductor structure 400 that are exposed in the region Ae are removed, such as by partial dicing, to expose the conductive contact 372 of the interconnect structure 314.

Referring to FIGS. 4 and 5I, method 100 includes a block 508 where the second semiconductor structure 400 is electrically connected to the first semiconductor structure 300. In some embodiments, the second MEMS structure 346 is electrically connected to the interconnect structure 314 over the first substrate 304 of the first semiconductor structure 300 by wire bonding. As shown in FIG. 5I, an interconnect wire WB-1 connects the conductive contact 462 and the conductive layer 370. In addition, in some embodiments, an interconnect wire WB-2 connects the conductive contact 372 and an external electrical component (not shown in FIG. 5I).

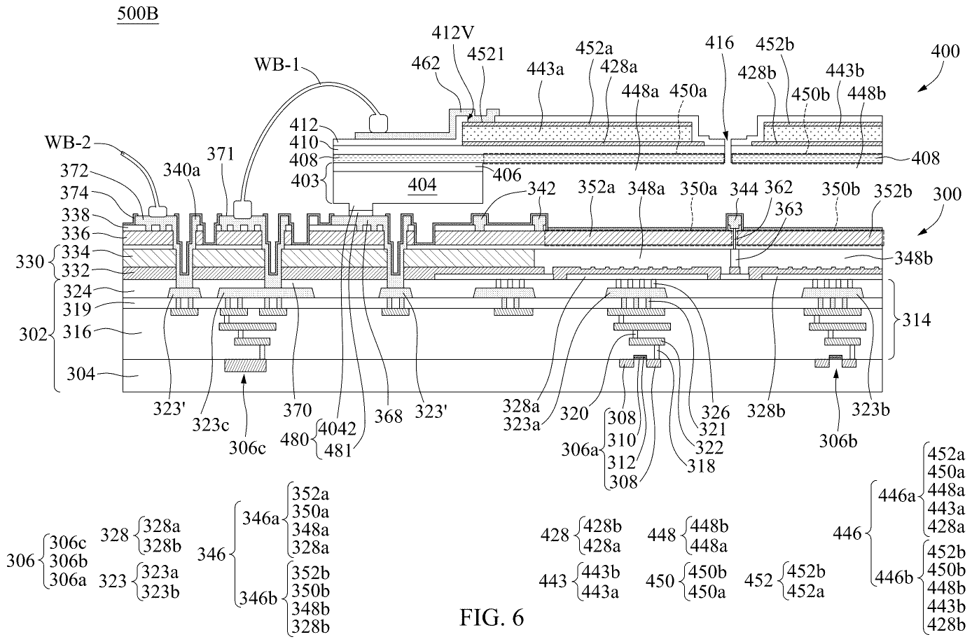

FIG. 6 illustrates a cross-sectional view of a semiconductor device 500B, in accordance with some embodiments of the present disclosure. The features/components in FIG. 6 that are similar to or identical to the features/components in FIG. 3 are designated with similar or the same reference numbers. Details of the arrangement, materials, and manufacturing methods of those similar or identical features/components shown in FIG. 6 are essentially the same as those discussed with reference to FIG. 3, and are not repeated herein. The difference between the semiconductor devices in FIG. 6 and FIG. 3 is in the contact region for landing the interconnect wire WB-1 at the first semiconductor structure 300.

In FIG. 3, the conductive layer 370 for landing the interconnect wire WB-1 is lower than the conductive layer 368 for landing the bond pad 481. In some embodiments, the portion of the interconnect structure 314 has been removed to expose the conductive layer 370 before bonding the second semiconductor structure 400 to the first semiconductor structure 300. Although this requires extra processes for removing the conductive portions and the dielectric portions to expose the conductive layer 370, the power and signal transmission path between the IC device 306c (e.g., a part of the CMOS circuit) in the first substrate 304 and the second MEMS structure (e.g., PMUT) can be reduced to reduce RC delay, thereby enhancing electrical performance.

In FIG. 6, the interconnect wire WB-1 connects the conductive contact 462 and the conductive layer 371. In some embodiments, the conductive layers 371 and 368 are formed by the same metal layer. Thus, the method for forming the semiconductor device 500B is simpler since there is no need to perform one or more extra steps for removing a portion of the interconnect structure 314. In addition, the wire bond (e. g, the interconnect wire WB-1) between the circuit in the first substrate 304 and the second MEMS structure 446 still facilitates the power and signal transmission speed.

In addition, a semiconductor device of some embodiments, for example, the semiconductor device 500A in FIG. 3, the semiconductor device 500B in FIG. 6, or another similar device having integrated PMUTs and CMUTs, can be further electrically connected to an external electrical component (e.g., a PCB) by the interconnect wire WB-2 The semiconductor device and the interconnect wire WB-2 can be further assembled to form an assembly structure, which is easy to be implemented in an electronic product.

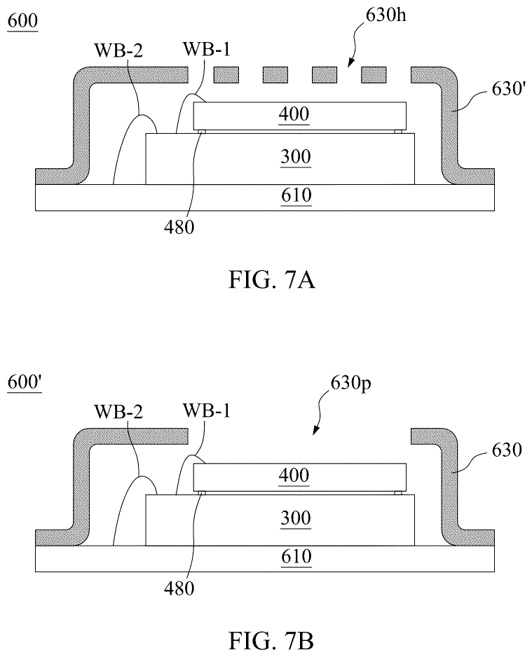

FIG. 7A illustrates a diagrammatic simplification of an assembly structure 600 including a semiconductor device in accordance with some embodiments of the present disclosure. FIG. 7B illustrates a diagrammatic simplification of another assembly structure 600′ including a semiconductor device in accordance with some embodiments of the present disclosure. In some embodiments, the semiconductor device 500A or 500B includes the first semiconductor structure 300 and the second semiconductor structure 400. The first semiconductor structure 300 includes one or more first MEMS devices, such as CMUTs. The second semiconductor structure 400 includes one or more second MEMS devices, such as PMUTs. Then, a lid (or cap) 630 with through holes 630h can be mounted on the external electrical component 610 to cover the semiconductor device 500A or 500B, thereby forming an assembly structure 600. In some embodiments, the lid 630 has several through holes 630h positioned above the semiconductor device 500A or 500B. For example, the through holes (or apertures) 630h are positioned above the second semiconductor structure 400 (e.g., PMUT). The shape of the through holes 630h may be square, round, rectangular, or any applicable shape when viewed from the top. In some other embodiments, a lid 630′ has an opening 630p positioned above the semiconductor device 500A or 500B, as shown in FIG. 7B. In addition, the opening 630p may expose the second semiconductor structure 400 (e.g., PMUT). The lid 630/630′ may be made of any conductive material (such as metal) or non-conductive material (such as resin). In addition, before mounting the lid 630, a protective material can be used to cover the interconnect wires WB-1 and WB-2 for added protection. Details of the arrangement, materials, and manufacturing methods of the first semiconductor structure 300 and the second semiconductor structure 400 can be essentially the same as those discussed in reference to FIG. 3 and FIG. 6, and are not repeated herein.

In addition, in the semiconductor devices of some embodiments, the first MEMS structure 346 may include several first MEMS devices such as capacitive micromachined ultrasonic transducers (CMUTs), and the second MEMS structure 446 may include several second MEMS devices such as piezoelectric micromachined ultrasonic transducers (PMUTs). Integrations of the numbers of the first and second MEMS devices may vary depending on practical designs. For example, one of the second MEMS devices may be positioned above one or more of the first MEMS devices. In addition, the shapes of the first and second MEMS devices in top view are not limited specifically.

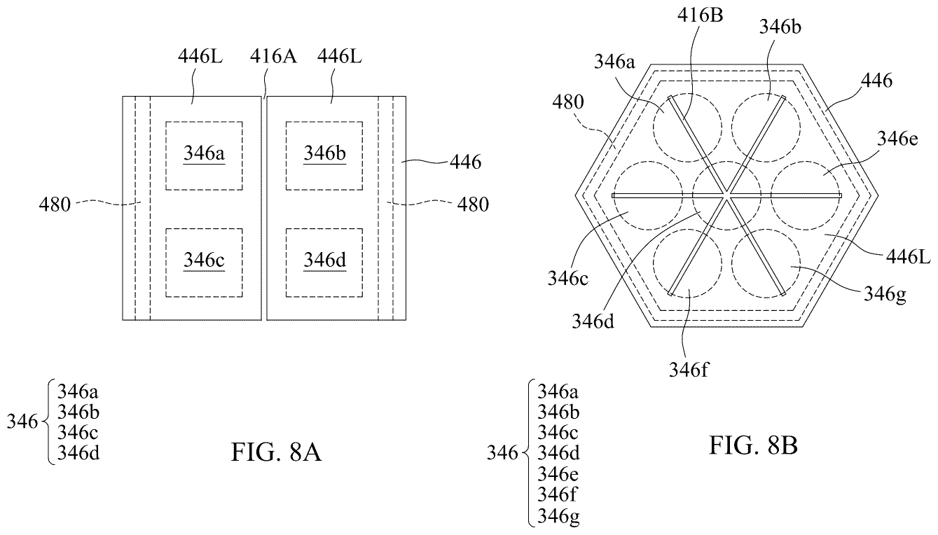

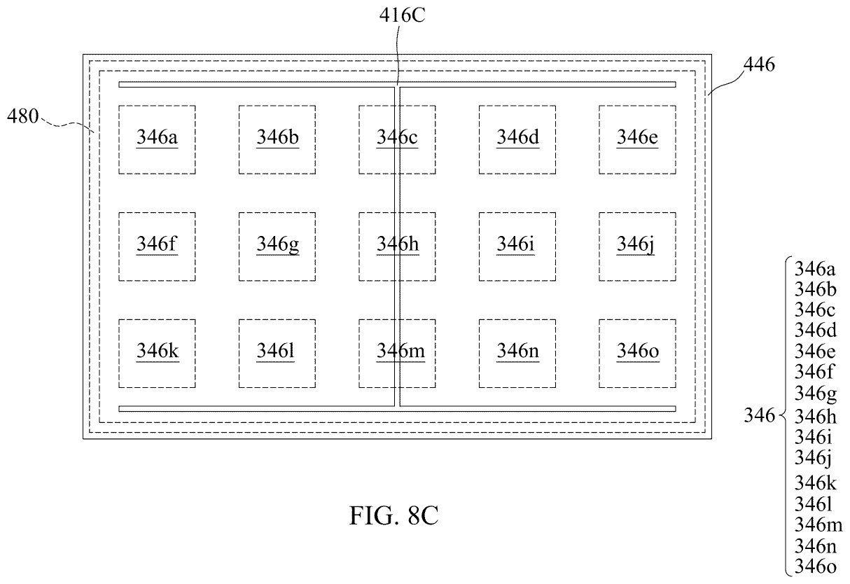

FIGS. 8A, 8B and 8C are schematic top views illustrating a region of a second MEMS structure 446 above the first MEMS structures 346, in accordance with some embodiments of the present disclosure.

In some embodiments, as shown in FIG. 8A, one of the second MEMS structures 446 is positioned corresponding to four of the first MEMS devices 346a, 346b, 346c, and 346d. In this exemplary configuration, the region of the second MEMS structure 446 has a square shape, and the regions of the first MEMS devices 346a and 346b each have a square shape when viewed from the top. The gap 416A defines two lever portions 446L (each having a rectangular shape in the top view) of the second MEMS structure 446. The lever portions 446L can be referred to as cantilevers over the first MEMS devices 346a and 346b. In addition, referring to FIG. 8A and FIG. 3, the bonding structure 480 extends substantially along the sides of the second MEMS structure 446. The bonding structure 480 has an elongate shape when viewed from the top.

In some embodiments, as shown in FIG. 8B, one of the second MEMS structures 446 is positioned corresponding to six of the first MEMS devices 346a, 346b, 346c, 346d, 346f and 346g. In this exemplary configuration, the region of the second MEMS structure 446 has a hexagonal shape, and the first MEMS devices 346a, 346b, 346c, 346d, 346f and 346g each have a circular shape when viewed from the top. The gap 416B defines six lever portions 446L (each having a triangular shape in the top view) of the second MEMS structure 446. The lever portions 446L can be referred to as cantilevers of the second MEMS structure 446. The gap 416B extends around two sides of each of the lever portions 446L when viewed from the top. In some embodiments, those lever portions may be driven to vibrate at the second frequency f2 simultaneously. In addition, referring to FIG. 8B and FIG. 3, the bonding structure 480 extends substantially along the shape of the second MEMS structure 446. The bonding structure 480 is a hexagonal ring and surrounds the first cavities of the first MEMS devices 346a, 346b, 346c, 346d, 346f and 346g when viewed from the top.

Accordingly, the first MEMS devices (e.g., 346a-346d in FIG. 8A; 346a-346f in FIG. 8B) may be arranged as an array (e.g., CMUT array), and the second MEMS structure 446 (or one of the second MEMS devices) is positioned correspondingly above the array of the first MEMS devices. Each of the first MEMS devices includes the first flexible membrane and the first cavity, as disclosed above. In some embodiments, the first MEMS devices of the array may be driven to vibrate simultaneously at the first frequency f1, thereby rapidly accumulating sound pressure in the corresponding second cavity of the second MEMS structure 446.

In some embodiments, as shown in FIG. 8C, one of the second MEMS structures 446 is positioned above several first MEMS devices (such as 346a, 346b, 346c, 346d, 346e, 346f, 346g, 346h, 346i, 346j, 346k, 346l, 346m, 346n, and 346o, which can be referred to as first MEMS devices 346) arranged as an array (e.g., CMUT array). In this exemplary configuration, the region of the second MEMS structure 446 has a rectangular shape, and the regions of the first MEMS devices 346 each have a square shape when viewed from the top. The gap 416C defines two lever portions 446L (each having a square shape in the top view) of the second MEMS structure 446. The lever portions 446L can be referred to as cantilevers of the second MEMS structure 446. The gap 416C extends around three sides of each of the lever portions 446L when viewed from the top. In addition, referring to FIG. 8C and FIG. 3, the bonding structure 480 extends substantially along the shape of the second MEMS structure 446. In some embodiments, the bonding structure 480 surrounds the first cavities of the first MEMS devices 346a to 346o when viewed from the top.

In addition, having one or more first MEMS structures (e.g., cMUTs) and one or more second MEMS structures (e.g., pMUTs) within an integrated structure as an ASIC assembly results in a relatively small overall device size. In addition, the integrated structure that includes one or more second MEMS structures placed over one or more first MEMS structures has a high interconnection capability between the second MEMS structures and the first MEMS structures. The relatively small size and high capability of interconnection can decrease resistance and/or RC delay among the second MEMS structures, the first MEMS structures, and the ASIC, thereby improving the performance of the integrated structure.

It should be noted that the integrations and shapes of the second MEMS structure 446, the first MEMS devices 346 and the bonding structure 480 in FIGS. 8A, 8B and 8C are provided only for exemplification, and they are not limited to the numbers, top-view shapes, and arrangements of the MEMS structure/devices in FIGS. 8A, 8B and 8C. For example, the first MEMS devices 346 may have circular, rectangular, square, or any suitable shape when viewed from the top. The second MEMS structure 446 (or the second MEMS devices) may have circular, rectangular, square, hexagonal, or any suitable shape when viewed from the top. In addition, the second MEMS structure 446 (or the second MEMS devices) and the first MEMS devices 346 may have similar shapes or different shapes when viewed from the top. Thus, the present disclosure is not limited to the exemplary patterns.

In addition, in some embodiments, the lever portions of the second MEMS structure (e.g., a PMUT) can be electrically connected and driven by the same stimulus frequency signal. In some embodiments, the lever portions of the second MEMS structure can be operated independently. In addition, several MEMS structures (e.g., PMUTs) may be arranged in an array, and one or more second MEMS structures in the array can be electrically connected or electrically independent of each other. In addition, the first MEMS structures (e.g., CMUTs) can be driven by the same stimulus frequency signal, or operated independently. The electrical connection between the MEMS structures of the same type (e.g., PMUTs or CMUTs) can be varied depending on design scheme.

Various embodiments or examples described herein offer several advantages. According to the embodiments of the present disclosure, a MEMS structure that acts as a ultrasound pump (such as CMUT) and another MEMS structure that acts as a frequency modulator (such as PMUT) are integrated to form a semiconductor device. The first MEMS structure (such as CMUT) is configured to vibrate at an ultrasound frequency (e.g., f1), and accumulate sound pressure in the cavity of the second MEMS structure. The second MEMS structure (such as PMUT) is configured to vibrate at another frequency (e.g., f2), resulting in a modulated wave at a modulated frequency (e.g., f). The actuation voltages are independently applied to the first and second MEMS structures to cause the vibration of the membranes. Thus, the semiconductor device of the embodiments provides a single transducer solution for replacing a conventional multi-speaker assembly. In addition, the MEMS structures of different types (such as PMUT and CMUT) can be integrated by bonding, for example, WoW bonding or CoW bonding, thereby providing a monolithic solution for speakers.

In addition, according to the embodiments, continuous vibration of the membrane of the first MEMS structure leads to a high sound pressure level (SPL) accumulated in the cavity of the second MEMS structure (e.g., PMUT). That is, the semiconductor device of the embodiments is able to generate sufficient pressure at both low and high frequencies. The semiconductor device of the embodiments is able to offer high SPL in low corner frequency. Therefore, the conventional speaker issue of small SPL at low corner frequency can be solved. According to the above-mentioned description, the semiconductor device of the embodiments has excellent sound pressure level (SPL) and frequency response control.

In addition, in some embodiments, the voltages, capacitances, and frequencies of the MEMS structures are directly controlled by ASIC CMOS, thereby enhancing the controllability and reliability of the semiconductor device. In addition, the semiconductor device of some embodiments adopts a capacitive-type MEMS structure, and would have low power consumption when it is implemented in a portable device.

In some embodiments, the semiconductor device that includes stacked MEMS structures of different types (e.g., PMUT and CMUT) reduces the signal path to minimize RC delay, enhancing electrical performance. The semiconductor device that includes stacked MEMS structures of different types (e.g., PMUT and CMUT) can be further molded into a package, which has a small form factor for wearable applications and other consumer products. In addition, the semiconductor device of some embodiments is fabricated using a semiconductor process, resulting in high yield and low performance variation. Also, the integration between different types of MEMS structures (e.g., PMUT and CMUT) using a semiconductor process simplifies the assembly complexity.

Some embodiments of the present disclosure provide a semiconductor device. The semiconductor device includes a first microelectromechanical system (MEMS) structure over a first substrate, and a second MEMS structure on a second substrate. The first MEMS structure includes a first flexible membrane and a first cavity between the first substrate and the first flexible membrane. The second substrate is bonded to a conductive layer over the first substrate, and the second MEMS structure is stacked above the first MEMS structure. The second MEMS structure includes a second flexible membrane overlying a second cavity of the second substrate, and the second cavity is positioned above the first cavity. The first MEMS structure and the second MEMS structure are independently coupled to an interconnect structure over the first substrate.

Some embodiments of the present disclosure provide a method of forming a semiconductor device. The method includes providing a first semiconductor structure that includes a first microelectromechanical system (MEMS) structure over a first substrate. The first MEMS structure includes a first flexible membrane and a first cavity between the first substrate and the first flexible membrane. The first flexible membrane is configured to vibrate at a first frequency. The method further includes providing a second semiconductor structure that includes a second MEMS structure on a second substrate. The second MEMS structure includes a second flexible membrane overlying a second cavity of the second substrate. The second flexible membrane is configured to vibrate at a second frequency. The method further includes bonding the second semiconductor structure to the first semiconductor structure, and the second MEMS structure is vertically stacked above the first MEMS structure. The method further includes electrically connecting the second MEMS structure to an interconnect structure over the first substrate.

Some embodiments of the present disclosure provide a method of forming a semiconductor device. The method includes providing an integrated circuit (IC) structure that includes an interconnect structure over a first substrate, and forming a first microelectromechanical system (MEMS) device over the IC structure. The first MEMS structure includes a first flexible membrane and a first cavity between the first substrate and the first flexible membrane, and the first MEMS structure is coupled to an IC device on the first substrate. The method further includes providing a second substrate with a second MEMS structure. The second MEMS structure includes a second flexible membrane overlying a second cavity of the second substrate. The method further includes bonding the second substrate to a conductive layer over the interconnect structure, and the second MEMS structure is stacked above the first MEMS structure. The second cavity is positioned between the second flexible membrane and the first flexible membrane.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A semiconductor device, comprising:
a first microelectromechanical system (MEMS) structure over a first substrate, wherein the first MEMS structure comprises a first flexible membrane and a first cavity between the first substrate and the first flexible membrane; and
a second MEMS structure on a second substrate that is bonded to a conductive layer over the first substrate, and the second MEMS structure stacked above the first MEMS structure, wherein the second MEMS structure comprises a second flexible membrane overlying a second cavity of the second substrate, and the second cavity is positioned above the first cavity;
wherein the first MEMS structure and the second MEMS structure are independently coupled to an interconnect structure over the first substrate.

2. The semiconductor device of claim 1, wherein the first MEMS structure is configured to be an ultrasound pump, and the second MEMS structure is configured to be a frequency modulator.

3. The semiconductor device of claim 1, wherein the first MEMS structure further comprises a first bottom electrode and a first top electrode, wherein the first cavity is formed between the first top electrode and the first bottom electrode, and the first top electrode comprise or be a part of the first flexible membrane.

4. The semiconductor device of claim 1, wherein the second MEMS structure further comprises:
a second bottom electrode on the second flexible membrane;
a second top electrode over the second bottom electrode; and
an actuator layer between the second top electrode and the second bottom electrode.

5. The semiconductor device of claim 1, further comprising:
a controller independently coupled to the first MEMS structure and the second MEMS structure,
wherein the controller independently applies actuation voltages to first MEMS structure and the second MEMS structure during operation of the semiconductor device.

6. The semiconductor device of claim 1, wherein a bonding structure vertically extends between the second substrate and the conductive layer over an interconnect structure on the first substrate, and the bonding structure is positioned within a periphery region of the second substrate.

7. The semiconductor device of claim 6, wherein the first MEMS structure includes first MEMS devices arranged as an array, when the second substrate is bonded to the conductive layer over the interconnect structure on the first substrate by the bonding structure, the bonding structure surrounds the first MEMS devices in top view.

8. The semiconductor device of claim 1, wherein the first MEMS structure is a capacitive micromachined ultrasonic transducer (CMUT), and the second MEMS structure is a piezoelectric micromachined ultrasonic transducer (PMUT).

9. The semiconductor device of claim 1, wherein the first MEMS structure includes a plurality of first MEMS ultrasonic transducers arranged as an array over the first substrate, and the second MEMS structure is positioned above the array of the first MEMS ultrasonic transducers correspondingly,
wherein each of the first MEMS ultrasonic transducers includes the first flexible membrane and the first cavity between the first substrate and the first flexible membrane.

10. A method of forming a semiconductor device, comprising:
providing a first semiconductor structure that comprises a first microelectromechanical system (MEMS) structure over a first substrate, wherein the first MEMS structure comprises a first flexible membrane and a first cavity between the first substrate and the first flexible membrane, and the first flexible membrane is configured to vibrate at a first frequency;
providing a second semiconductor structure that comprises a second MEMS structure on a second substrate, wherein the second MEMS structure comprises a second flexible membrane overlying a second cavity of the second substrate, and the second flexible membrane is configured to vibrate at a second frequency;
bonding the second semiconductor structure to the first semiconductor structure, wherein the second MEMS structure is vertically stacked above the first MEMS structure; and
electrically connecting the second MEMS structure to an interconnect structure over the first substrate.

11. The method of claim 10, wherein the first frequency is an ultrasound frequency.

12. The method of claim 10, wherein the second cavity is positioned above the first cavity and shields the first cavity.

13. The method of claim 10, wherein the second substrate is bonded to a conductive layer over the first substrate by thermal compression bonding.

14. The method of claim 10, wherein the second MEMS structure is electrically connected to the interconnect structure by wire bonding.

15. The method of claim 10, further comprising:
electrically connecting a conductive contact of the interconnect structure to an external electrical component; and
mounting a lid on the external electrical component to cover the second semiconductor structure and the first semiconductor structure stacked vertically, thereby providing an assembly structure package.

16. A method of forming a semiconductor device, comprising:
providing an integrated circuit (IC) structure that comprises an interconnect structure over a first substrate;
forming a first microelectromechanical system (MEMS) structure over the IC structure, wherein the first MEMS structure comprises a first flexible membrane and a first cavity between the first substrate and the first flexible membrane, and the first MEMS structure is coupled to an IC device on the first substrate;
providing a second substrate with a second MEMS structure, wherein the second MEMS structure comprises a second flexible membrane overlying a second cavity of the second substrate; and
bonding the second substrate to a conductive layer over the interconnect structure, and the second MEMS structure stacked above the first MEMS structure, wherein the second cavity is positioned between the second flexible membrane and the first flexible membrane.

17. The method of claim 16, further comprising:
electrically connecting the second MEMS structure to the interconnect structure over the first substrate.

18. The method of claim 16, wherein the first MEMS structure is configured to be an ultrasound pump to vibrate at a first frequency, and the second cavity of the second substrate acts as an ultrasound pumping chamber.

19. The method of claim 18, wherein the second MEMS structure is configured to be a frequency modulator to vibrate at a second frequency, and the second frequency is less than the first frequency.

20. The method of claim 16, wherein the IC structure is a complementary metal-oxide-semiconductor (CMOS) structure, and the IC device that is coupled to the first MEMS structure is a part of a CMOS circuit.
